(19) United States
(12) Patent Application Publication
(10) Pub. No.: US 2001/0003603 A1
(43) Pub. Date: Jun. 14, 2001

(54) CVD FILM FORMATION METHOD AND APPARATUS USING MOLDED SOLID BODY AND THE MOLDED SOLID BODY

(75) Inventors: KAZUHIRO EGUCHI, CHIGASAKI-SHI (JP); MASAHIRO KIYOTOSHI, SAGAMIHARA-SHI (JP); KATSUHIKO HIEDA, YOKOHAMA-SHI (JP); KATSUYA OKUMURA, YOKOHAMA-SHI (JP)

Correspondence Address: FINNEGAN HENDERSON FARABOW GARRETT &, DUNNER LLP, 1300 I STREET NW, WASHINGTON, DC, 200053315

(73) Assignee: KABUSHIKI KAISHA TOSHIBA

(21) Appl. No.: 09/361,621

(22) Filed: Jul. 27, 1999

(30) Foreign Application Priority Data
Jul. 28, 1998 (JP) 10-212970

(51) Int. Cl. C23C 16/00

(52) U.S. Cl. 427/248.1

(57) ABSTRACT

A solid raw material such as a powdery material is pressure-molded into a disk form to form a molded solid body. The molded solid body is heated to produce a source gas. The source gas is used in a film formation step in accordance with a chemical vapor deposition method. When the molded solid body is used, the source gas can be produced in an amount larger than the case where the powdery raw material is heated to obtain the source gas. In this case, an amount of carbon introduced into the film can be reduced compared to the case of using a liquefied material obtained by dissolving the raw material in a solvent. Furthermore, it is possible for a user to easily replace the raw material with a new one by using the molded solid body.

### BACKGROUND OF THE INVENTION

The present invention relates to a method and apparatus for forming a film in accordance with the chemical vapor deposition and by using a source gas, which is obtained by subliming a solid raw material or by liquefying the solid raw material by heating it to a melting point or more and then vaporizing it. The present invention also relates to a molded solid body (or molded material) for generating the source gas for use in the film formation method and apparatus.

Recently, semiconductor devices have been advanced in function. With the advancement of the semiconductor devices, novel materials which have never been used in the semiconductor devices, begin to be introduced into part of the semiconductor devices. With this tendency, requirement has been increased for forming a film using the novel material in accordance with the chemical vapor deposition (CVD) method. The novel material to be used in the CVD method is preferred to be a gaseous form at room temperature. However, in most cases, the novel materials are present in liquid or solid state. In particular, when the solid-state raw material is used, it is difficult to generate a source gas required for the CVD and send it to a CVD reaction vessel. This is because the vapor pressure of the solid material is generally low.

It is effective to heat the raw material to obtain the source gas required for CVD from the solid material. However, when the raw material compound thermally labile is used, there is the uppermost limitation in temperature in a conventionally-used sublimation method. It is therefore impossible to obtain a sufficient amount of the source gas required for CVD. To overcome the upper-limit problem, sometimes employed is a method which includes the steps of dissolving the solid material in a solvent to obtain a liquid and heating the liquid to vaporize it while controlling a flow rate thereof. For example, a solid organic metal compound is dissolved in an organic solvent to change it a liquid state. In this method, however, extra substances must be employed other than the raw material. These extra substances often have adverse effects on the CVD process and the film obtained by the CVD.

On the other hand, the thin-film conventionally used in the semiconductor device can be improved in performance if the raw material is changed. To attain high-performance CVD and to obtain the high-performance film by the CVD, it is extremely effective to chose the raw material from a wide variety range. As the material, a gaseous material at room temperature is the most convenience for the CVD. However, if the raw material is limited to the gaseous substance, the selection range is narrow. Then, if the range for the raw material is enlarged to a solid material, the CVD raw material can be selected from an extremely wide range of materials. As a result, it is possible to obtain a high-performance CVD thin film.

As described above, one of the effective means for obtaining a high-performance semiconductor device can be provided if the CVD method using the solid material is realized.

We will explain it more specifically by taking one of the semiconductor devices, DRAM, as an example.

With a tendency of the semiconductor device (DRAM) toward higher capacitance, a processing size (patterning size) has been decreased, and thereby a capacitor cell area has been reduced. Even if the cell area is reduced, capacitance per cell cannot be reduced due to limitations such as a bit-line capacity, a soft error or refresh characteristics. Therefore, to obtain a requisite capacitance, a cell having a three dimensional capacitor structure such as a trench-type structure or a stack-type structure is used.

However, in the DRAM of a post IG-bit generation, the three dimensional capacitor structure becomes more complicated and miniaturized. It is therefore predicted difficult to manufacture the DRAM.

Then, the material having a higher dielectric constant than a conventionally-used silicon oxide/silicon nitride composite film is tried to be used as a capacitor insulating film. As the material with a high dielectric constant, there are SrTiO₃(STO), (Br, Sr)TiO₃(BST) and the like.

Even if the high dielectric material such as STO or BST is used, it is impossible to realize a capacitance required for device operation by using a planar capacitor as the DRAM is further integrated. Therefore, in order to obtain the requisite capacitance, it is necessary to form the cell by using the three dimensional capacitor structure. To form a high dielectric thin film such as a BST film, the chemical vapor deposition (CVD) is a prospective method since it is excellent in covering the step structure and in forming a film having a uniform thickness on a substrate having a complicated structure.

However, when the BST film is formed by the CVD method, a problem resides in that there is no raw material compound having sufficient vaporization characteristics, namely, vapor pressure. In particular, this problem is serious when the IIa group (in the periodic table) element such as Ba or Sr is used. Raw materials for Ba and Sr are few including powdery Ba(THD)₂, Sr(THD)₂, where THD=2,2,6,6-tetramethyl-3,5-hepthanedione: C₁₁H₁₉O₂.

FIG. 8 is a cross-sectional view showing a schematic structure of a raw material feeding portion for use in sublimating source gas by using a carrier gas. The apparatus is most frequently used for forming a film by generating a source gas from a powdery material and then feeding the source gas thus obtained into a reaction vessel.

A raw material vessel 181 is filled with an inert gas together with a powdery material 183. In some cases, the raw material vessel 181 is filled only with the powdery material 183 without using the inert gas to thereby produce a vacuum in the vessel. The powdery material 183 is loaded in an amount of at least about 50-100 g, and sometimes, 1 kg or more. The reason why the raw material is loaded in a large quantity is that the raw material is denatured if exposed to the air. Therefore, the raw material is usually loaded into the vessel by a manufacturer under a well-controlled atmosphere. Another reason is that the frequency of raw material exchange is reduced. However, it is impossible for a user to easily replace the raw material without denaturing it.

In the sublimation method, how large amount of the source gas should be fed from a source gas feed passage 187, is determined by a raw material temperature, an inner pressure of the raw material vessel, and a carrier gas flow rate. To obtain the feed amount of the source gas in a constant amount, it is necessary to control the raw material temperature, the raw material reaction vessel, and the carrier gas flow rate. Note that the raw material temperature is controlled by placing the raw material vessel 181 within an oven 182 and controlling the temperature of the oven 182.

The pressure of the raw material vessel 182 is controlled in the feed-back manner by a pressure control valve 186 while the inner pressure of the raw material vessel is monitored by a pressure sensor 185. The flow rate of the carrier gas introduced from the carrier gas inlet passage 185 is controlled by a mass-flow controller (not shown).

When this apparatus is used, a large amount of raw material is maintained under heating for a long time. The raw material is therefore required so as not to be degraded or decomposed with time at a temperature at which the raw material is vaporized. However, Ba(THD)₂ and Sr(THD)₂ are gradually decomposed into non-volatile substances when they are heated to a temperature of 220° C. or more. As a result, the vaporization amount decreases with time. Hence, to avoid the decomposition, the upper limit in temperature for heating the raw material must be set. Since the upper limit is set in the heating temperature as described, an upper limit is automatically set in the vapor pressure of the raw material which is specified by the raw material temperature. In particular, when the raw material whose vaporization temperature was close to the decomposition temperature is used, it was difficult to supply a vapor pressure required for the CVD.

To explain more specifically, in the case where a source gas was supplied by sublimating powdery Ba(THD)₂, the upper limit of the heating temperature of the raw material was 215° C. However, even if Ba(THD)₂ and Sr(THD)₂ are heated to almost the upper limit of the heating temperature, about 210° C., the obtained vapor pressure was 0.1 Torr or less. It is meant that the sufficient vapor pressure cannot be obtained.

In the sublimation method using a powdery raw material, which is most frequently used for feeding a source gas in the CVD method, if the temperature of the raw material container is increased in order to increase the vapor pressure, the raw material in the container is decomposed. As a result, a stable film formation is not attained.

On the other hand, another method is proposed for feeding a thermal vapor from a solid material by Japanese Patent Application KOKAI Publication No. 6-158328. In this method, a solid material is dissolved in an organic solvent such as THF (tetrahydrofuran) to convert it into a liquid and the obtained liquid material is heated to vaporize by an evaporator.

In this method, a gas is introduced into a pressurized gas inlet passage 193 to thereby send out a liquid raw material 192 from a liquid raw material container 191 into a liquid raw material controller 194. Subsequently, the liquid raw material 192 is introduced into the evaporator 195 while controlling the flow rate thereof by the liquid raw material controller 194. Thereafter, the liquid raw material is heated to vaporize. The obtained source gas is fed together with a carrier gas which is introduced from the carrier gas inlet passage 196, into a reaction vessel through a source gas feed passage 197. In this way, a film is formed.

In this method, only the evaporator 195 is increased in temperature but the raw material container 191 for storing a large quantity of liquid material is maintained at room temperature. Therefore, the raw material in the raw material container 191 will not be decomposed. Furthermore, since retention time for the raw material in the high-temperature evaporator 195 (at which the raw material is exposed to a high temperature) is short, the raw material can be vaporized at a temperature higher than in the sublimation method. As a result, the supply amount of the raw material can be increased compared to the sublimation method.

However, a solvent is required other than the raw material. Since the solvent is an organic solvent, the amount of carbon introduced into the CVD film increases, degrading electric characteristics of the BST film. When an oxide thin film such as a BST film is formed, it is desirably formed under an oxidation atmosphere by introducing an oxide agent such as O₂ gas. However, if the organic solvent such as THF is used, the oxidation gas is consumed in a large amount in decomposing the organic solvent. As a result, the oxidation gas required for the BST film formation is not secured, degrading the characteristics of the resultant BST film. In addition, a gas is generated when the organic solvent is decomposed. The gas decreases tightness between a lower electrode serving as an underlying substrate and the BST film. As a result, the electrode is peeled off during the BST film formation process.

As described above, in the method of supplying a source gas through the sublimation, there are problems in a low vapor pressure and a slow film formation speed. In addition, if the temperature of the raw material container is increased in order to increase the vapor pressure, the raw material in the container is decomposed, preventing a stable film formation.

Furthermore, in the method of obtaining a source gas by vaporizing a liquid-state raw material, the amount of carbon incorporated into the obtained film increases, inducing deterioration in the electric characteristics and tightness.

### BRIEF SUMMARY OF THE INVENTION

An object of the present invention is to provide a method and apparatus for forming a film by a chemical vapor deposition method, capable of reducing an amount of carbon introduced in the formed film while securing a sufficient flow rate of a source gas, and to provide a molded solid body for use in chemical vapor deposition method and apparatus.

To achieve the aforementioned object, the present invention provides a method for forming a film on a substrate by using a chemical vapor deposition method, comprising the steps of: generating a source gas by heating to sublimate a molded solid body formed by molding or unifying a solid raw material; and forming a film on the substrate by using at least the source gas.

In another aspect of the present invention, there is provided a method for forming a film on a substrate by using a chemical vapor deposition method, comprising the steps of: generating a source gas by heating a molded solid body by molding or unifying a solid raw material at a melting point or more; and forming a film on the substrate by using at least the source gas.

In still another aspect of the present invention, there is provided an apparatus for forming a film on a substrate by using a chemical vapor deposition method, comprising: at least one raw material feed portion for generating a source gas by sublimating or vaporizing by heating a molded solid body formed by molding or unifying a solid material to a melting point or more; and a reaction vessel for forming a film by a chemical vapor deposition method using the source gas, wherein the at least one raw material feed portion comprises: a raw material container; heating means for heating at least a region within the raw material container, having the molded solid body placed therein; pressure control means for controlling inner pressure of the raw material container; at least one molded solid body holder placed within the raw material container, for holding the molded solid body; and a source gas send-out port for sending out the source gas in the raw material container to the reaction vessel.

In a further aspect of the present invention, there is provided a molded solid body for producing a source gas used in forming a film on a substrate in accordance with a chemical vapor deposition method, wherein the solid material is formed by molding or unifying a solid raw material.

Now, preferable embodiments of the present invention will be described below.

The raw material container comprises a raw material container body having an opening portion at the bottom and a raw material container lid connected to the bottom portion of the raw material container via a sealing material. The raw material container lid is disposed below the heating means, to which the molded solid body holder is connected via a divisional wall for suppressing a temperature increase of the sealing material and the container cover due to radiation heat from the heating means. As the sealing material, O-ring or a metal is used.

The raw material container has a carrier gas inlet passage for feeding a carrier gas which is used for sending out the source gas into the reaction vessel, and an evacuation port connected to a pump for evacuating the raw material container.

The molded solid body of the present invention is formed by molding or unifying a solid raw material which generates a source gas for use in the CVD film formation.

Any material is used as the solid raw material to be used in the present invention as long as it is solid at room temperature and applicable in the CVD. For example, an organic compound of an alkaline earth metal (metal of Group IIa) such as Ba(THD)₂ and Sr(THD)₂ where THD=2, 2, 6, 6, tetramethyl-3, 5-heptanedyone: C₁₁H₁₉O₂, an inorganic compound such as TiI₄, an organic/inorganic noble metal compound, may be used.

When the powdery raw material is pressure-molded into a predetermined shape, numerous air holes may be included in the solid raw material. In this case, the air holes are preferably present in a ratio within the range of 10% to 90% in volume based on the entire raw material.

As the predetermined shape, there are plate, disk, column and spherical forms. In the case where no or little surface deterioration of the molded solid body occurs and the molded solid body is used at a temperature lower than the melting point thereof, it is preferable to design the shape of the molded solid body so as to make the surface as large as possible. On the other hand, in the case where surface deterioration may occur and the molded solid body is used as a molten material by heating it at a temperature higher than the melting point, it is preferable to design the shape of the molded solid material so as to the surface as small as possible.

[Function]

The present invention has the following functions/effects by the aforementioned constitution.

When the solid raw material is molded into a molded solid body having a predetermined shape, a user can easily handle and replace it. Hence, it becomes unnecessary to load a large quantity of raw material into the raw material container, as is in the conventional case. As a result, the raw material is better to be stored in an amount only required for the film formation, in the raw material container. As a result, the temperature of the raw material container can be increased to the extent that decomposition of the raw material taking place within the film formation process is negligible. At the same time, it is possible to drastically increase a vapor amount compared to the sublimation method using a powdery raw material. In addition, the molded solid body can be replaced with a fresh molded solid body every one to several film deposition process. As a result, it is possible to obtain vapor always in a constant amount, enabling well-controlled film formation.

In the case where the raw material is unstable when exposed to the air, when such a raw material is molded into a predetermined shape and then exposed to the air, only the surface of the molded solid body is degraded but the inner portion is not degraded. Since the inner portion remains intact even if its surface is degraded, the molded solid body can produce the source gas when sublimated. In this case, in order to reduce the area of a degradation-susceptible portion near the surface, the molded solid body is desirably formed into a shape having a surface area as small as possible, for example, a disk and a spherical form.

According to the present invention, any extra substance other than the CVD raw material, such as an organic solvent, is not used, it is possible to eliminate an adverse effect of carbon derived from an organic solvent upon the CVD film and the underlying substrate.

When the film-formation gas is generated by heating the molded solid body to a melting point or more, if the viscosity of the molten molded solid body is high, the shape of the molded solid body maintains its original shape without presenting a drastic breakdown. As a result, the surface area of the molded solid body is virtually the same as that used at a melting point or less. Hence, the vapor amount is not reduced. On the contrary, a vaporization rate is increased by raising the temperature, with the result that a supply amount of the source gas can be increased. Furthermore, if the molded solid body has a low viscosity, it can be used by devising the shape of raw material holder in such a way that the liquefied raw material does not run out. For example, it is effective to use a raw material holder in the shape of dish or the like.

When the raw material stable to the air is used at a melting point or less, it is better to make the surface of the molded solid body as larger as possible in order to increase a vaporization efficiency. The surface area can be enlarged by, for example, forming projections/depressions and pleats on the surface. The amount of the source gas can be increased by improving the vaporization properties of the raw material.

Additional objects and advantages of the invention will be set forth in the description which follows, and in part will be obvious from the description, or may be learned by practice of the invention. The objects and advantages of the invention may be realized and obtained by means of the instrumentalities and combinations particularly pointed out hereinafter.

### BRIEF DESCRIPTION OF THE SEVERAL VIEWS OF THE DRAWING

The accompanying drawings, which are incorporated in and constitute a part of the specification, illustrate presently preferred embodiments of the invention, and together with the general description given above and the detailed description of the preferred embodiments given below, serve to explain the principles of the invention.

FIG. 1 is a schematic cross-sectional view of a structure of a film formation apparatus according to a first embodiment;

FIG. 2 is a view showing a shape of a molded solid body to be stored in a raw material container of the film formation apparatus of FIG. 1;

FIG. 3 is a view showing a shape of a molded solid body to be stored in a raw material container of the film formation apparatus of FIG. 1;

FIG. 4 is a characteristic graph showing the dependency of flow rate of a source gas upon pressure of the raw material container;

FIG. 5 is a schematic cross-sectional view showing a structure of a raw material container constructed in a different manner as in FIG. 1;

FIG. 6 is a schematic cross-sectional view showing a structure of a raw material container constructed in a different manner as in FIGS. 1 and 5;

FIG. 7 is a view showing a shape of a molded solid body to be stored in the raw material container of FIG. 6;

FIG. 8 is a cross-sectional view of a raw material container of a conventional film formation apparatus; and

FIG. 9 is a cross-sectional view of a raw material container of a conventional film formation apparatus.

### DETAILED DESCRIPTION OF THE INVENTION

Embodiments of the present invention will be explained below with reference to the accompanying drawings.

[First Embodiment]

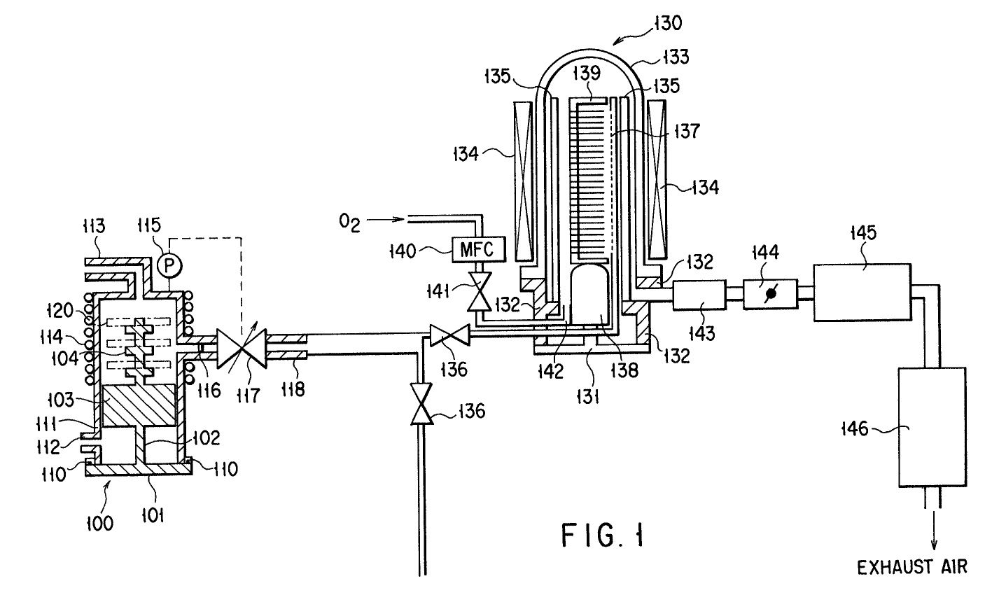

FIG. 1 is a schematic cross sectional view of a CVD apparatus according to a first embodiment of the present invention.

First, a raw material feed portion including a raw material container 100 will be explained. The raw material container 100 constituted of a raw material container body 111 made of SUS having an opening portion of 20 mm in outer diameter at the bottom of the raw material container body 111. The opening portion is closed with a raw material container lid 101. The raw material container body is closed airtight with the cover via a sealing material 110. As the sealing material 110, an O-ring or a metal gasket is used. The O-ring seal is preferably used since the raw material can be replaced more easily. However, the metal gasket seal is preferably used in the case where a gas released from the O-ring seal have an adverse effect on the CVD.

A carrier gas inlet passage 112 is provided in a lower side surface of the raw material container body 111. A vacuum exhaust port 113, which is connected to a pump (not shown), is provided in an upper surface of the raw material container body 111.

Furthermore, a heater 114 is attached along an outer wall of the raw material container body 111. The inside atmosphere of the raw material container 100 can be increased to a temperature up to 300° C. by heating the main container 111 by the heater 114. Note that the inner temperature of the raw material container 100 can be controlled by a thermocouple (not shown) and a temperature controller inserted in an appropriate place within the raw material container 100.

A gas feed-out passage 118 is connected to a side portion of the raw material container body 111 via a conductance control valve 117. The conductance control valve 117 works in concert with a pressure sensor 115 to control the inner pressure of the raw material container 100 at a constant value. Furthermore, a filter 16 is disposed between the raw material container 100 and the conductance control valve 117, for shutting out powdery molded solid body as set forth later.

The raw material container lid 101 is equipped with a support column 102. Furthermore, the support column 102 is formed in a continuous form with a pressure divisional wall 103 and a molded solid body holder 104. The support column 102, the pressure divisional wall 103 and the molded solid body holder 104 are disposed in the raw material container 100.

Next, a reaction vessel 130 connected to the raw material container 100 will be explained. A main reaction vessel 133, which is made of quartz glass, is placed on a stainless-steel manifold 132. A lower opening end of the manifold 132 is closed with a stainless-steel cap 131. The manifold is thus maintained airtight.

An inner pipe 135 made of quartz is placed on an overhang of the center of the manifold 132 for the purpose of improving thermal uniformity and rectification of a gas. A heater 134 (manufactured by Supercantal) is attached around a main reaction vessel 133 as an exterior thermal source for externally heating the entire reaction vessel 133.

A heat insulating barrel made of quart glass and a substrate port 139 made of quart glass are mounted on the cap 131. Note that a silicon substrate of 8 inch can be mounted on the substrate port 139 up to 120 sheets.

The substrate on which a thin film is to be formed is mounted on the substrate port 139 on the cap 131, outside the reaction vessel 130 and then loaded into the reaction vessel 130 together with the substrate port 139.

A source gas feed nozzle 137 is interposed between the inner pipe 135 and the substrate port 139 and connected to the gas feed-out passage 118 via a switch valve 136. An oxygen gas inlet pipe 142, which is connected to the oxygen bomb (not shown) via a mass-flow controller (MFC) 140 and a valve 141, is interposed between the heat insulating barrel 138 and the inner pipe 135.

Note that the pipe from the source gas feed-out passage 118 to the manifold 132, the switch valve 136, and the manifold 132 are heated to at least the temperature of the raw material container in order to prevent condensation of the source gas in the middle of the passage.

A dry pomp 145 is connected to the manifold 132 via an open/shut valve 143 and a pressure control valve 144, for evacuating the reaction vessel 130. An exhaust gas treatment unit 146 is connected on the exhaust side of the dry pomp 145.

Next, we will explain how to feed a gas required for the CVD film formation by using this apparatus.

First, the raw material cover 101 is removed. Since airtightness between the raw material cover 101 and the raw material container body 111 is maintained by the O-ring 110, the cover 101 can be easily and swiftly removed.

Since the temperature of the opening portion of the lower portion of the raw material container body 111 is low since it is not heated by the heater, high temperature gas within the raw material container 100 is rarely mixed to the gas (low in temperature) outside the container 100. Therefore, the container cover 101 and the O-ring sealing 110 are prevented from being increased in temperature since pressure divisional wall 103 prevents heat radiation from the upper portion which is heated by the heater 114.

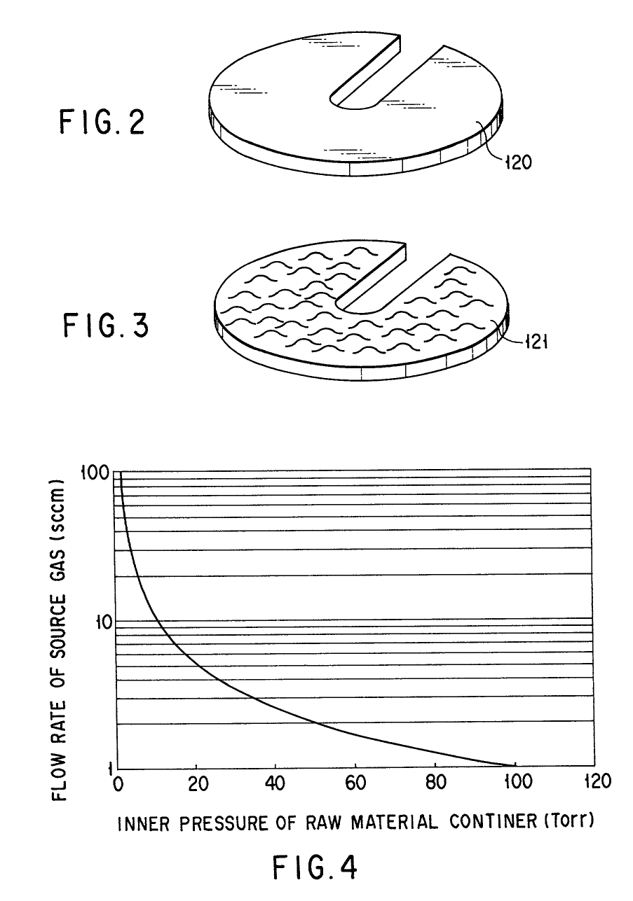

Then, a molded solid body 120 is fixed on the molded solid body holder 104 attached to the raw material container lid 101 thus removed. As the molded solid body 120, pellet-form Ba(THD)₂ (shown in FIG. 2) molded by pressurizing powdery Ba(THD)₂, is used. Ba(THD)₂ has a density of about 0.2-0.26 g/cm³ before the pressure-molding. After the pressure-molding, the density increases 5 folds, 1-1.3 g/cm³. The molded solid body 120 is formed into a disk of 10 mm in diameter and 3 mm in thickness. To set it on the molded solid body holder 104, the molded solid body 120 is partly cut away as shown in FIG. 2, thereby facilitating replacement of the molded solid body. When the raw material does not deteriorate when exposed to the atmosphere, the surface of the molded solid body 120 may be formed uneven as shown in FIG. 3 in order to increase a vaporization rate.

In the case where the molded solid body is degraded when exposed to the atmosphere, only the surface thereof is degraded and the inside portion is not degraded. Even if the surface is degraded, the deteriorated surface does not adversely affect the sublimation.

If the raw material is formed into a thin pellet, the surface area involved in raw material vaporization can be increased. Since the powdery raw material is molded into a pellet, it is possible to prevent contamination of the film formed on the substrate with particles during the CVD. Even if the power particles are scattered, the particles are removed by the filter 116 attached to the gas feed passage 118.

The molded solid body is handled by placing it on a platform having almost the same shape as the molded solid body. Preferably, the molded solid body is integrally formed with the platform. This is because the molded solid body acquires a stable strength by using the platform although the molded solid body itself is fragile due to pressure molding.

The inner space of the raw material container is heated in order to sublimate the molded solid body. In the case where the raw material is heated to a temperature close to a melting point of the raw material, the solid raw material sometimes melts. For example, the melting points of Ba(THD)₂, Sr(THD)₂, Ti(i-OPr)₂(THD)₂ are about 195-210° C. (where i-OPr=OC₃H₇), 135-260° C. (Sr(THD)₂ may form polymer (trimer and tetramer), and thus the melting temperature may change depending on the content ratio of trimer and tetramer) and 160° C. Since the molded solid body is mounted on the table while it is set on the platform, even if the raw material is melted, the melting material can be prevented from running down into the container. The platform is desirably formed into a plate having a recess for placing the molded solid body.

After Ba(THD)₂ pellet is fixed onto the molded solid body holder 104 and the raw material container lid 101 having the molded solid body holder 104 attached thereto is fixed to the raw material container body 111 with the sealing material 110 interposed between them, the raw material container 100 is evacuated to a vacuum.

After the raw material container 100 is fully evacuated, Ar gas is introduced into the container 100 through the carrier gas inlet passage 112 at a flow rate of 10 sccm. When the raw material easily reacts with remaining air when heated, it is preferred to repeat the evacuation operation and the Ar gas loading. Subsequently, the inner pressure of the raw material container 100 is controlled constant by the pressure sensor 115 and the conductance control valve 117. In this embodiment, the inner pressure of the raw material container 100 was set at 10 Torr.

The container 100 of this embodiment has the vacuum evacuation port 113 and the carrier gas inlet passage 112 which is disposed below the pressure divisional wall 103. Since the carrier gas inlet passage 112 is disposed below the pressure divisional wall 103 to flow the carrier gas upwardly from the lower portion, the stagnation of gas is not observed in a space below the pressure divisional wall 103. Furthermore, since the vacuum exhaust port 113 is disposed, the container can be vacuum-evacuated. This apparatus is particularly effective in the case where the raw material is sensitive to air contamination and enables to stably provide a large amount of source gas.

When the pressure became constant, the inner space of the raw material container 100 was heated to 230° C. by the heater 114. After the temperature became constant, the amount of Ba(THD)₂ gas sent out from the source gas send-out passage 118 became as constant as 1.5×10⁻⁴ mol/min with respect to time. The flow rate was constant for about 15 minutes.

After 15 minutes, the amount of Ba(THD)₂ gas sent out from the source gas send-out passage 118 drastically decreased to a zero point.

As described in the above, according to this embodiment, it was found that a solid raw material for gas can be stably vaporized and sent out as a gas having a low vapor pressure.

Furthermore, the raw material container lid 101 was removed and the inside of the container 100 was investigated. As a result, the solid raw material was completely consumed. It is therefore confirmed that the molded solid body was completely vaporized and sent out as the source gas. From this fact, it was found that remarkable decomposition of Ba(THD)₂ did not take place at 230° C. for 15 minutes.

The obtained uppermost temperature was 215° C. in the case where the powdery raw material is sublimated. Therefore, the present invention makes it possible to increase the raw material temperature (uppermost temperature) by 15° C. In the case of Ba(THD)₂, if the powdery raw material is molded by pressure-molding into a molded solid body, it was confirmed that the source gas can be supplied for a required period of time even if it is heated to 300° C. In this case, a larger amount of source gas can be fed than in the case of the raw material temperature of 230° C. However, it is necessary to increase the amount of raw material loaded for one time, for example, by increasing the thickness of the pellet and the sheet number in accordance with the increase in the source gas feed amount.

Next, while Ar gas is supplied as a carrier gas through the carrier gas inlet passage 112 at a flow rate of 100 sccm, thereby changing the inner pressure of the raw material container 100 within the range of 5 Torr to 100 Torr, the flow rate of the Ba(THD)₂ gas fed out from the gas send-out passage 118 was checked.

FIG. 4 is a characteristic graph showing the relationship between the inner pressure of the raw material container and the flow rate of the supplied source gas. Note that the container temperature was 230° C., the saturated vapor pressure of Ba(THD)₂ at 230° C. was 1 Torr.

As shown in FIG. 4, when inner pressure of the raw material container is set at 50 Torr, the flow rate of the source gas results in about 2 sccm. In contrast, in the case where Ba(THD)₂ having a concentration of Ba(THD)₂/THF of 0.3 mol/l is allowed to flow at a flow rate of 0.4 cc/min by using the conventional raw material feed apparatus shown in FIG. 9, the flow rate of the feed gas becomes 2.7 sccm. The value of 2.7 sccm is almost the upper limit when a liquid raw material supply method is employed in consideration that there is a limitation in increasing concentration of the raw material and that clogging of the material takes place in the vaporizer.

When the inner pressure of the raw material container of this embodiment decreases to about 50 Torr, it is possible to feed the gas in the amount corresponding to the gas feed amount when the liquid raw material is used. Furthermore, in the liquid raw material supply method, a dilute gas such as Ar gas is required to feed at a flow rate of 300-400 sccm. In addition, a solvent, THF is fed in the form of gas simultaneously with the source gas supplied at a flow rate of about 85 sccm. Whereas, in the present invention, since only Ar gas is supplied as the carrier gas only at a flow rate of 100 sccm. Hence, in view of partial pressure of the raw material, the source gas can be supplied at a higher flow rate than in the liquid raw material supply method.

Furthermore, when the pressure of the raw material container is reduced, the effect can be further increased. For example, the flow rate of the source gas rapidly increases under the pressure of the raw material container, 10 Torr or less. For example, the source gas flows at a flow rate of about 10 sccm at an inner pressure of 10 Torr. In this case, only Ar gas flows at a rate of 100 sccm other than the source gas, so that the partial pressure of the source gas can be increased in proportional to the feed amount of the source gas. The lowermost pressure of the raw material container is determined by the pressure of the CVD reaction vessel, and a pressure loss between the raw material feed apparatus and the reaction vessel. Furthermore, in the case where the solid raw material having an uneven surface (shown in FIG. 3) is used, the pressure of the raw material container can be reduced compared to the case where the solid raw material (shown in FIG. 2) is used since vapor amount is high. It was therefore confirmed that the feed amount of the raw material can be further increased.

It is principally better if the pressure of the raw material container is set at a higher value than that of the reaction vessel. This is because, if there is no difference in pressure between the raw material container and the reaction vessel, it is impossible to feed the source gas to the reaction vessel. For example, when the pressure of the reaction vessel is 1 Torr, it is good enough for the raw material container to have a pressure of 1 Torr or more, assuming that the pressure loss between the raw material feed portion and the reaction vessel is ignored. However, in practice, the pressure loss is present between the raw material feed portion and the reaction vessel. Therefore, it is necessary to set the pressure of the reaction vessel at a higher value in consideration of the pressure loss.

However, as described, the amount of the source gas to be generated can be increased if the pressure of the raw material container is reduced. To reduce the pressure of the raw material container as well as to reduce the pressure loss between the raw material container and the reaction vessel as much as possible, the connection distance between the raw material container and the reaction vessel must be reduced.

Due to this, the connection distance between the raw material container and the reaction vessel is preferred to be 1 m or less. If the connection distance is larger than 1 m, it is impossible to reduce the pressure of the raw material container since the pressure loss increases. As a result, the source gas cannot be supplied in the same amount as in conventional liquid raw material supply method. Since the pressure of the raw material container is lower and lower, the generation amount of the raw material can be increased. Hence, desirably, the connection distance between he raw material container and the reaction vessel is 50 cm or less.

If the connection distance between the raw material container and the reaction vessel is reduced, the source gas is rarely condensed at the connection portion. Accordingly, the control of the source gas supply can be improved. Furthermore, the pressure loss can be suppressed by reducing the number of curves of the pipe at the connection portion or by bending the curve at an obtuse angle. It is therefore preferred that the raw material container be linearly connected to the reaction vessel.

The film is formed by fitting the molded solid body and repeating vaporization and feed-out operation for a plurality of times. In the same manner as in the film formation mentioned above, a flow rate of Ar gas is set at 10 sccm, a pressure of the raw material container at 10 Torr, and a temperature of the raw material container 100 at 230° C. A trial test was performed 10 times under the aforementioned conditions. As a result, it was found that the concentration of the feed-out source gas and the feed-out time thereof are as constant as 1.5×10⁻⁴ mol/min and 10 minutes, respectively. It was further found that the fluctuation is within ±1%.

As mentioned above, it is demonstrated that the raw material does not deteriorate when the raw material is replaced if this embodiment is used, and that the source gas can be supplied constantly. This is due to the following improvements: First, the contamination of the inner atmospheric gas of the raw material container with the air is suppressed as much as possible when the molded solid body is replaced by providing a difference in temperature of the heating portion of the raw material container and the portion near the cover, setting the low temperature portion at the lower part. Second, even if the raw material is exposed to the air, only the surface of the pellet is degraded since the raw material is formed into a pellet.

As described in the foregoing, according to this embodiment, compared to the conventional sublimation method, it is possible to increase the feed amount of the source gas tremendously and stably. This is because the raw material can be easily replaced every 1 to 10 times of film deposition operation, due to the pellet form of the raw material. Furthermore, this is because the heating time of the raw material is reduced, so that the temperature of the raw material can be set higher than that of the sublimation method which requires a long-time heating.

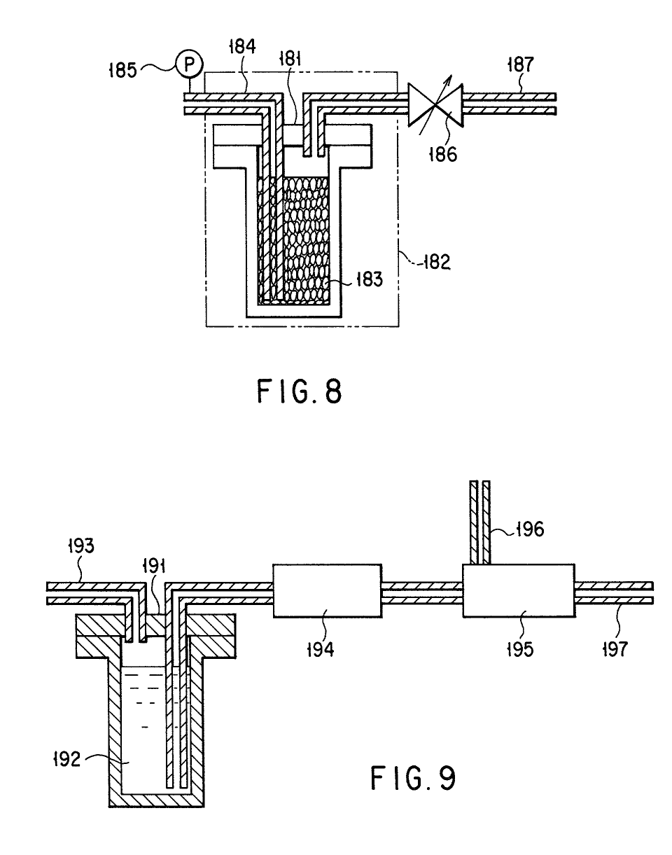

The present inventors processed Sr(THD)₂, Ti(i-OPr)₂(THD)₂, and formed them into molded solid bodies. Using the thus molded solid bodies, films were formed in the same conditions as mentioned above, at the same time, films were formed by using a conventional apparatus as shown in FIG. 8, for comparison. More specifically, the case of the present invention using the replaceable molded solid body was compared to the conventional case using sublimation, with respect to the feed amount of the raw material and feed stability thereof. As a result, similarly to the case f Ba(THD)₂, in either case of Sr(THD)₂ and Ti(i-OPr)₂(THD)₂, it was successful in increasing the feed amount of the raw material tremendously compared to the sublimation methods. Furthermore, since the raw material is formed into a pellet, the raw material was able to be supplied in a constant amount with a difference of ±1% or less.

In the film formation by using the sublimation method using a powdery material, a carrier gas flow passage is formed in the powdery raw material when the carrier gas is allowed to flow in the powdery raw material. As a result, an area in which a carrier gas comes into contact with the raw material decreases. Due to this, the amount of the source gas generated is reduced, so that the supply amount of the source gas to the reaction vessel sometimes becomes unstable. However, in the raw material container according to this embodiment, a flow passage of the carrier gas is not formed in the solid raw material, the source gas can be supplied in a stable amount.

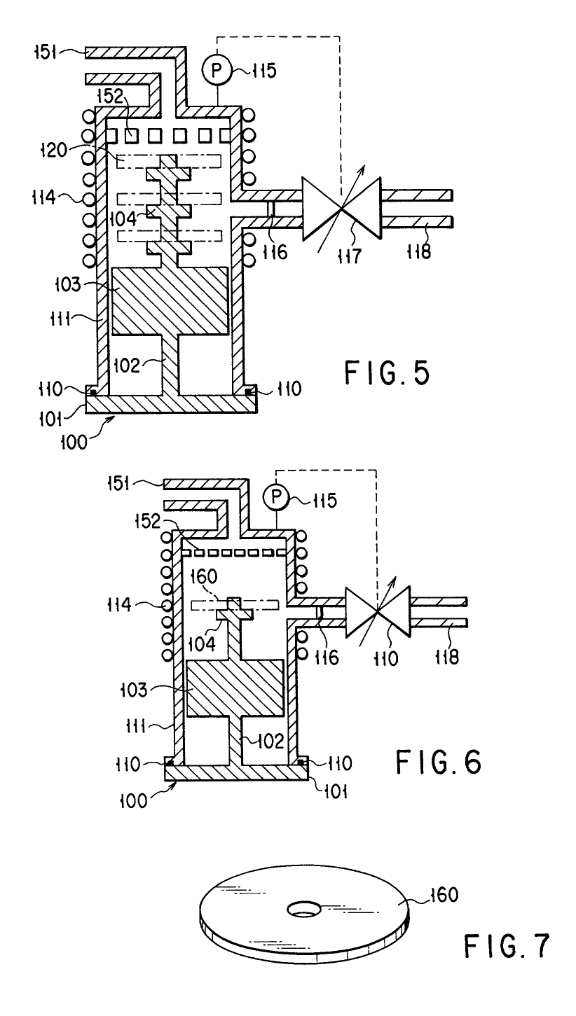

Note that the raw material is not sensible to air contamination, the raw material container shown in FIG. 5 may be used. The raw material container has a carrier gas inlet passage 151 provided in the upper portion of the raw material container body but does not have a vacuum evacuation port. A shower head 152 is provided near the outlet of the carrier gas inlet passage 151 to uniformly distribute the carrier gas from an inlet passage 151 within the container 100. Note that, like reference numerals are used in FIG. 5 to designate like structural elements corresponding to those of FIG. 1 and detailed explanation will be omitted for brevity's sake.

The clean level and vacuum level of this container are low compared to those of the raw material container shown in FIG. 1. However, the container is simplified in structure, so that the manufacturing cost for the apparatus can be suppressed.

In the aforementioned embodiment, a plurality of molded solid bodies are disposed in the raw material container to obtain a sufficient amount of the source gas. However, if only one molded solid body is sufficient enough to provide a sufficient amount of the source gas, it is possible to use a raw material container in which only one molded solid body 160 is stored. In this case, instead of using the molded solid body partially cutaway, a donut form molded raw material 160 (shown in FIG. 7) may be used. Note that, like reference numerals are used in FIG. 6 to designate like structural elements corresponding to those of FIG. 1 and detailed explanation will be omitted for brevity's sake.

[Second Embodiment]

As described in the first embodiment, when the heating temperature of a molded solid body is close to the melting point thereof, the molded solid body sometimes melts. When the heating temperature of the molded solid body exceeds to the melting point thereof, different effects from those described in the first embodiment are produced.

In this film formation case, the raw material Ba(THD)₂ was used in the form of a disk (shown in FIG. 2). As the raw material holder for holding the molded solid body, a board having a larger diameter than that of the molded solid body was used to prevent running-out of the raw material when melted.

In the case where the molded solid body is placed on the raw material holder while the molded solid body is mounted on a platform having a diameter larger than that of the molded solid body, the raw material holder may be smaller in diameter than that of the molded solid body. Even if the molded solid body is melted but it has a high viscosity, the molded solid body rarely changes in shape and does not leak out. In this case, the raw material holder may be a simple board. However, if the molten raw material is low in viscosity and thus easily flows out, the raw material holder or the platform for holding the molded solid body is preferably formed into a plate shape. This is because it is effective to prevent the molded solid body from melting or flowing out.

A film was formed by setting the temperature of the solid raw material, Ba(THD)₂, at 230° C. Note that the melting point of Ba(THD)₂ was about 195 to 210° C.

The molded Ba(THD)₂ is melted at 230° C. Since the viscosity of the molten matter is high, the molten matter retains its original disk shape and does not greatly lose the shape. Hence, the surface area of the molded solid body is almost the same as that of the case where it is used at a temperature of a melting point or less, so that the vaporization amount does not decrease. On the contrary, the supply amount of the source gas increases since a vaporization rate increases due to an increase in temperature.

On the other hand, when a powdery raw material is heated to a temperature of a melting point or more by using a conventional apparatus shown in FIG. 8, the raw material is liquefied and bubbles are evolved. However, the viscosity of the liquefied raw material is high, so that the bubbles must be formed against high viscosity resistance. As a result, stable bubbling cannot be obtained, which means that the source gas cannot be supplied stably.

If the source gas cannot be supplied stably, the film formation rate becomes unstable, which means that it is difficult to control the thickness of the formed film. Furthermore, in the case of multi-element raw material such as (Ba, Sr)TiO₃, the film is not formed uniformly in composition and in film characteristics.

For example, in the case of (Ba, Sr)TiO₃, the melting point of Sr(THD)₂ are about 135-260° C. The melting point of Ti(i-OPr)₂(THD)₂ is about 160° C. Hence, the raw material can be used by increasing its temperature up to the melting point or more to the extent that the raw material is not degraded during a single film formation process.

[Third Embodiment]

In this embodiment, a(Ba, Sr)TiO₃ was deposited to form a thin film by using the film formation apparatus shown in FIG. 1.

As the raw materials, Ba(THD)₂, Sr(THD)₂, Ti(i-OPr)₂(THD)₂ were used. Each of the raw materials was molded into a pellet form shown in FIG. 2. Three raw material feed portions shown in FIG. 5 were used for Ba(THD)₂, Sr(THD)₂, and Ti(i-OPr)₂(THD)₂, respectively.

A pellet-form raw material was fitted in the manner shown in the first embodiment. Each of the source gas feed passages of the raw material feed portion is introduced in a reaction vessel for use in the CVD film formation.

The supply conditions of the source gas are as follows: Temperatures of the raw material containers of Ba(THD)₂, Sr(THD)₂, and Ti(i-OPr)₂(THD)₂ were 230° C., 230° C., and 150° C., respectively. The pressure of the reaction vessel was set at 1 Torr. The flow rate of the carrier gas was set at 10 sccm. The flow rate of the carrier gas and the pressure of the raw material container were controlled closely and carefully so as to obtain a (Ba, Sr)TiO₃ composition where Ba/Sr=1 and (Ba, Sr)/Ti=1. Furthermore, other than the source gas, oxygen gas was supplied at a flow rate of 2000 sccm to the reaction vessel.

As a substrate, a Si oxide substrate having a Ru thin film deposited thereon was used. The Ru thin film was formed by sputtering or a CVD method using Ru(C₅H₅)₂ as a raw material.

In this case, since Ru(C₅H₅)₂ was a solid material, Ru(C₅H₅)₂ was pressure-molded into a pellet (shown in FIG. 2). The substrate thus constructed was introduced into the reaction vessel, and thereafter, the reaction vessel was evacuated to a vacuum.

Subsequently, the temperature of the reaction vessel was increased up to a film formation temperature. In this embodiment, the film formation temperature was set at 500° C. After the temperature was stabilized, oxygen gas was introduced into the reaction vessel.

Thereafter, the source gas was introduced into the reaction vessel by using the feed apparatus of the present invention, and then, deposition of the (Ba, Sr)TiO₃ thin film was initiated. The source gas was introduced in the same manner as shown in the first embodiment. The film formation was performed by introducing the source gas for 5 minutes and stopped by terminating the feed of the source gas into the reaction vessel. After completion of the film formation, the temperature of the reaction vessel was decreased and the substrate was taken out from the reaction vessel.

The (Ba, Sr)TiO₃ thin film thus obtained had a film thickness of 25 nm. The composition of the film was (Ba_{0.5}Sr_{0.5})TiO₃. Compositions of sample points on the film distributed along the thickness direction were checked. As a result, the compositions did not virtually vary between the points. Hence, it was confirmed that the source gas was fed constantly. The remaining carbon amount in the film felt within a detection limit (1%) by Auger electron spectroscopy. In addition, no exfoliation of Ru substrate was observed.

The present inventors tried to form another film in the same manner by replacing the solid raw material with a new one after completion of the film formation. As a result, the obtained thin film had excellent reproducibility with respect to film thickness and composition. It was therefore demonstrated that the raw material is fed with excellent reproducibility even if the raw material pellet is replaced.

[Comparative Example]

On the other hand, for comparison, a (Ba, Sr)TiO₃ thin film was formed by using a conventional liquid raw material supply apparatus shown in FIG. 9. The raw materials were prepared by dissolving Ba(THD)₂, Sr(THD)₂, and Ti(i-OPr)₂(THD)₂ into THD(C₄H₈) at a concentration of 0.3 mol/l.

The temperatures of the vaporizers for vaporizing Ba(THD)₂, Sr(THD)₂, and Ti(i-OPr)₂(THD)₂ were set at 230° C., 230° C., and 170° C., respectively. The flow rates of liquid raw materials thus prepared were 0.5, 0.5, and 1.0 sccm. Other film formation conditions and manners were the same as shown in the aforementioned embodiments of the present invention.

The amount of carbon remaining in the (Ba, Sr)TiO₃ thin film obtained in this comparative example was about 5%. In addition, it was observed that Ru was partially peeled off from the substrate.

In the aforementioned embodiments of the present invention, the carbon remaining in the (Ba, Sr)TiO₃ thin film was low. This is because THF serving as a solvent was not used. Furthermore, Ru was not peeled off in the embodiments. This is because THF was not used in the present invention, so that a THF decomposed gas does not have an adverse effect on Ru.

In the foregoing, the present invention has been explained with reference to the embodiments. The present invention makes it possible to supply a large amount of source gas which was not able to be obtained unless the conventional liquid raw material supply method is used. Furthermore, since an organic solvent other than the raw material is not used unlike the conventional liquid raw material supply method, it is possible to eliminate harmful effects upon the underlying substrate, such as contamination of the film with carbon ascribed to an organic solvent, and exfoliation of the underlying film. It is a matter of course that the temperature of the source gas required for forming a CVD film is not obtained in a conventional sublimation method, with the result that film deposition on the substrate is rarely performed.

[Fourth Embodiment]

In this embodiment, a SrRuO₃ thin film was actually deposited on a substrate by using the film formation apparatus shown in FIG. 1.

As the raw material, Sr(THD)₂ and Ru(THD)₃ were used. Each of them was formed into a pellet shown in FIG. 2. Two raw material feed portions shown in FIG. 5 were used for Sr(THD)₂ and Ru(THD)₃, respectively.

Each of the pellet was fitted in the same manner as shown in the first embodiment. Each of the source gas feed passages of these raw material feed portions was introduced into a CVD reaction vessel.

The feed conditions of the raw materials were as follows: the temperatures of the raw materials, Sr(THD)₂, and Ru(THD)₃ were set at 230° C. and 200° C. Each of the pressures of the raw material containers was set at 1 Torr. Each of the flow rates of the carrier gases was set at 10 sccm. Each of the flow rates of the carrier gases and each of the pressures of the raw material containers were closely and carefully controlled so as to obtain the composition of SrRuO₃ where Sr/Ru=1. Oxygen gas other than the source gas was supplied into the reaction vessel at a flow rate of 2000 sccm.

As a substrate, a Si oxide substrate was used. After the substrate was introduced into the reaction vessel, the reaction vessel was evacuated to a vacuum. The temperature of the reaction vessel was increased to a film formation temperature. In this embodiment, the film formation temperature was set at 450° C. After the temperature was stabilized, oxygen gas was introduced into the reaction vessel.

Subsequently, the source gas was introduced into the reaction vessel using the feed apparatus of the present invention to initiate deposition of a SrRuO₃ thin film. The source gas was introduced in the same manner as shown in the first embodiment.

The film formation was performed by introducing the source gas for 5 minutes and stopped by terminating the feed of the source gas into the reaction vessel. After completion of the film formation, the temperature of the reaction vessel was decreased and the substrate was taken out from the reaction vessel.

The film thickness of the SrRuO₃ thin film thus obtained was 20 nm. The composition of the film was SrRuO₃. Compositions of sample points on the film distributed along the thickness direction were checked. As a result, there was no variation in composition. It was therefore confirmed that the source gas was constantly supplied. The amount of carbon remaining in the film fell within a detection limit (1%) by the Auger electron spectroscopy.

The present inventors tried to form another film by replacing the pellet with a new one after completion of the film formation. As a result, the obtained thin film was excellent in reproducibility in film thickness and composition. It is therefore confirmed that the raw material was supplied with a good reproducibility despite the replacement of the raw material pellet.

[Fifth Embodiment]

In this embodiment, a TiN thin film was deposited by using the film formation apparatus shown in FIG. 1.

As the raw material, TiI₄ was used. The raw material was formed into a pellet shown in FIG. 2. The raw material feed portion shown in FIG. 5 was used herein.

The solid raw material was fitted in the same manner as shown in the first embodiment. Each of the source gas feed-out passage of the raw material feed portions was introduced in a CVD reaction vessel.

The conditions for supplying the source gas were as follows: The temperature of the raw material container was set at 180° C. The pressure of the raw material container was set at 1 Torr. As the carrier gas, N₂ was supplied at a flow rate of 10 sccm. Other than the source gas, ammonia (NH₃) gas was supplied to the reaction vessel at a flow rate of 2000 sccm.

As the substrate, a Si oxide was used. After the substrate was introduced into the reaction vessel, the reaction vessel was evacuated to a vacuum. Subsequently, the temperature of the reaction vessel was increased to a film formation temperature. The film formation temperature was set at 400° C. in this embodiment. After the temperature was stabilized, ammonia gas was introduced into the reaction vessel.

Subsequently, the source gas was introduced into the reaction vessel by using the feed apparatus of the present invention to initiate formation of a TiN thin film. The source gas was introduced in the same manner as shown in the first embodiment. The film formation was performed by introducing the source gas for 5 minutes and stopped by terminating the feed of the source gas into the reaction vessel. After completion of the film formation, the temperature of the reaction vessel was decreased and the substrate was taken out from the reaction vessel.

The thickness of the TiN film thus obtained was 20 nm and the resistivity thereof was sufficiently low.

The present inventors tried to form another film by replacing the pellet with a new one after completion of the film formation. As a result, the obtained thin film was excellent in reproducibility in film thickness and composition. It is therefore confirmed that the raw material was supplied with a good reproducibility in accordance with the present invention even if the raw material pellet is replaced.

In the conventional CVD, the TiN film is formed from, as a raw material, TiCl₄, TiI₄, and an organic metal such as Ti[N(CH₃)₂]₄ or Ti[N(C₂H₅)₂]₄. In the case of TiCl₄, there is no problem in supply amount and control since the raw material is supplied in liquid form. However, the film formation temperature must be 600° C. or more in order to obtain a good-quality film. If TiI₄ is used, the film formation temperature can be decreased to about 400° C. However, TiI₄ has a problem. Due to a solid material and a thermally unstable material, it has been difficult to feed TiI₄ constantly. The present invention made it possible to supply TiI₄ constantly by pressure-molding it into a pellet. The present inventors confirmed that if the organic metal such as Ti[N(CH₃)₂]₄ or Ti[ N(C₂H₅)₂]₄ was pressure-molded into a molded solid body, the source gas can be supplied constantly.

The present invention is not limited to the aforementioned embodiments. In the embodiments, the molded solid body is replaced with a new one every film formation step. The frequency for replacing the molded solid body is determined by the temperature at which the raw material is actually used. More specifically, if the temperature of the raw material is suppressed low, it is possible to suppress deterioration of the solid raw material, with the result that the raw material can be used for longer time. Therefore, a plurality of film formation operations can be performed by a single raw material loading. However, the feed amount of the source gas decreases if the temperature is decreased.

For example, in the case of Ba(THD)₂, if the temperature of the raw material container is set at 230° C., no deterioration of the raw material is observed for about 2 hours. Since a single film formation takes 10 minutes, 10 times film formation operation can be performed by a single raw material loading. However, if the temperature of the raw material container is set at 300° C., only one film forming operation can be made without deterioration of the raw material. Nevertheless, since the temperature of the raw material is high, the raw material can be supplied in an amount larger by more than one-digit order of magnitude, as compared to the case of 230° C.

The pellet raw material is not limited to those used in the embodiments. The types of the raw materials are not limited. More specifically, the raw material for a (Ba, Sr)TiO₃ film is not limited to Ba(THD)₂, Sr(THD)₂, and Ti(i-OPr)₂(THD)₂. The present invention can be applied to all chemical vapor deposition methods using a solid raw material and produces the same effects as obtained in the embodiment.

The shape of the solid raw material is not limited to a pellet. Any shape including a cubic form can be used. For example, in the case where the raw material is labile if exposed to the air, the raw material may be pressure-molded into a spherical form in order to reduce the surface area as much as possible.

Furthermore, the skeletal essential of the present invention resides in that a raw material to be used in the CVD method is prepared by pressure-molding a solid raw material into a molded solid body. Therefore, the present invention can be widely applied to the CVD using the solid raw material. More specifically, solid-form organic metals including organic metals such as Pb, Zr, and Ti for use in formation of a Pb (Zr, Ti)O₃ CVD thin film, organic metals such as Sr, Bi, and Ta for a Sr₂Bi₂TaO₉ CVD thin film, an organic metal such as Ta for a Ta₂O₅ CVD thin film, may be effectively used in the present invention. Furthermore, the present invention can be effectively applied to not only the organic metal compounds but also inorganic compounds such as TiI₄ as long as the compounds are used in the solid form. The present invention can be put in practical use by modifying it in various ways within the gist of the present invention.

As explained in the foregoing, according to the present invention, the raw material can be replaced easily by using a molded solid body processed into a predetermined shape. In addition, it is possible to reduce an amount of carbon introduced into a formed film during the chemical vapor deposition film formation process while maintaining a sufficient flow amount of the source gas.

Additional advantages and modifications will readily occur to those skilled in the art. Therefore, the invention in its broader aspects is not limited to the specific details and representative embodiments shown and described herein. Accordingly, various modifications may be made without departing from the spirit or scope of the general inventive concept as defined by the appended claims and their equivalents.

1. A method for forming a film on a substrate by using a chemical vapor deposition method, comprising the steps of:
generating a source gas by heating to sublimate a molded solid body formed by molding a solid raw material; and
forming a film on the substrate by using at least the source gas.

2. The method according to claim 1, wherein the molded solid body is formed by pressure-molding a powdery raw material:

3. A method for forming a film on a substrate by using a chemical vapor deposition method, comprising the steps of:
generating a source gas by heating a molded solid body formed of a solid raw material at a melting point or more; and
forming a film on the substrate by using at least the source gas.

4. The method according to claim 3, wherein the molded solid body is formed by molding a powdery material under pressure.

5. An apparatus for forming a film on a substrate by using a chemical vapor deposition method, comprising:
at least one raw material feed portion for generating a source gas by sublimating or vaporizing by heating a molded solid body formed by molding a solid material to a melting point or more; and
a reaction vessel for forming a film by a chemical vapor deposition method using the source gas, wherein
said at least one raw material feed portion comprises:
a raw material container;
a heater for heating at least a region within the raw material container, having the molded solid body placed therein;
pressure controller for controlling inner pressure of the raw material container;
at least one molded solid body holder placed within the raw material container, for holding the molded solid body; and
a source gas send-out port for sending out the source gas in the raw material container to the reaction vessel.

6. The apparatus according to claim 5, wherein the raw material container comprises a raw material container body having an opening and a raw material container lid covering the opening of the raw material container via a sealing material.

7. The apparatus according to claim 6, wherein the raw material container further comprises a carrier gas inlet passage for introducing a carrier gas for sending out the source gas into the reaction vessel, and an evacuation port connected to a pump for evacuating the raw material container.

8. The apparatus according to claim 7, wherein the raw material container further comprises:
a pressure divisional wall
a first support column one end of which is fixed on an inner surface of the raw material container lid, for supporting the pressure divisional wall within the raw material container body; and
a second support column for supporting said at least one raw material holder on the pressure divisional wall.

9. The apparatus according to claim 8, wherein the carrier gas inlet passage has an opening end provided in the raw material container body, said opening end locating below the pressure divisional wall.

10. The apparatus according to claim 8, further comprising a connector for feeding a source gas into the reaction vessel from the raw material container, wherein said connector has a length of 1 m or less.

11. The apparatus according to claim 5, wherein said raw material holder has a plate shape.

12. A molded solid body for producing a source gas used in forming a film on a substrate in accordance with a chemical vapor deposition method, wherein the molded solid body is formed by molding a solid raw material.

13. The molded solid body according to claim 12, wherein the solid raw material is a powdery material.

14. The molded solid body according to clam 13, wherein the molded solid body has a plate shape.

15. The molded solid body according to claim 13, wherein the molded solid body has a spherical shape.

16. The molded solid body according to claim 13, wherein the powdery material is an organic compound of an alkaline earth metal or a complex thereof.

17. The molded solid body according to claim 13, wherein the powdery material is a noble metal compound or a complex thereof.

18. The molded solid body according to claim 13, wherein the molded solid body has an uneven surface.

19. The molded solid body according to claim 13, wherein the molded solid body is placed on a platform therefor.

20. The molded solid body according to claim 13, wherein the molded solid body and the platform are formed into a united body.

21. The molded solid body according to claim 20, wherein the platform is formed in a plate shape.
